(19) United States
(12) Patent Application Publication
(10) Pub. No.: US 2019/0115518 A1
(43) Pub. Date: Apr. 18, 2019

(54) ENERGY CONVERSION SYSTEM FOR A TURBO ENGINE, GEAR BOXES OR BEARING HOUSINGS AND A TURBO ENGINE

(71) Applicant: Rolls-Royce Deutschland Ltd & Co KG, Blankenfelde-Mahlow (DE)

(72) Inventor: Bastian KACPROWSKI, Berlin (DE)

(21) Appl. No.: 16/088,898

(22) PCT Filed: Apr. 11, 2017
(86) PCT No.: PCT/EP2017/058688

§ 371 Date: Sep. 27, 2018

(30) Foreign Application Priority Data
Apr. 20, 2016 (DE) 10 2016 107 303.2

(51) Int. Cl. H01L 35/30; F02C 7/12; F02C 7/36

(52) U.S. Cl. CPC H01L 35/30; F02C 7/12; F05D 2220/76; F05D 2260/20; F02C 7/36

(57) ABSTRACT

An energy conversion system for a turbo engine, characterized in that at least one gear box and/or at least one bearing housing for converting thermal energy into electrical energy is/are thermally coupled to at least one thermoelectric element. Furthermore, the invention concerns a gear box, a bearing housing and a turbo engine.

The invention concerns an energy conversion system of a turbo engine with the features of claim 1, a gear box or a bearing housing of a turbo engine with the features of claim 10 and a turbo engine with the features of claim 11.

In modern turbo engines, in particular aircraft engines, electrical units, such as for example an electronic engine controller (EEC, electronic engine control), are used that must be supplied with current. In principle, it is known from WO 01/61768 A1 to use thermoelectric elements in aircraft.

There is in particular the objective of making the electrical supply of turbo engines more efficient.

The objective is achieved by an energy conversion system with the features of claim 1.

In this case, at least one gear box and/or at least one bearing housing for converting thermal energy into electrical energy are thermally coupled to at least one thermoelectric element. Thermal energy that can be converted into useful electrical energy accumulates to a considerable extent in both gear boxes and in bearing housings.

In this case, in one embodiment the at least one thermoelectric element is thermally coupled via a housing of the at least one gear box.

In a further embodiment, the electrical energy generated by the at least one thermoelectric element can be used to operate at least one other unit of the turbo engine, in particular for an oil pump of the power gear box and/or a controller of the turbo engine. Because the production of electrical energy depends on the operating state of the turbo engine, in one embodiment a current control arrangement is used to control the electrical energy generated by the at least one thermoelectric element as a function of the operating state of the turbo engine, in particular to supply the other units entirely or partly with current.

In one embodiment with a gear box or a bearing housing, at least one deflector for oil droplets is used for thermal coupling to the at least one thermoelectric element. Thermal energy is transferred by oil droplets in both gear box housings and in bearing housings.

Furthermore, in one embodiment of the at least one gear box is embodied as a power gear box for mechanically coupling at least one low-pressure compressor stage to at least one turbine stage or as a further gear box.

In this case, the at least one thermoelectric element is disposed in an aircraft engine, wherein the at least one thermoelectric element is disposed in the axial direction partly or entirely between the tip of the inlet cone and the power gear box.

Furthermore, the at least one thermoelectric element can be at least partly disposed on the housing of the at least one gear box or the at least one bearing housing, in particular entirely around the circumference of the housing of the power gear box and/or on the core engine.

Furthermore, one embodiment of the energy converter can comprise a means of guiding cold air to the cold site of at least one thermoelectric element.

The object is achieved by a gear box or a bearing housing with the features of claim 10 and a turbo engine with the features of claim 11.

The invention is described in connection with the exemplary embodiments represented in the figures. In the figures:

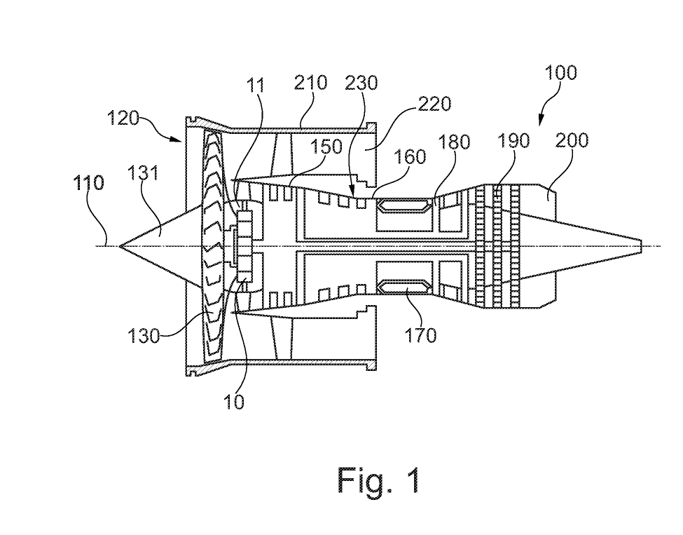

FIG. 1 shows a schematic representation of an aircraft engine as an embodiment of a turbo engine;

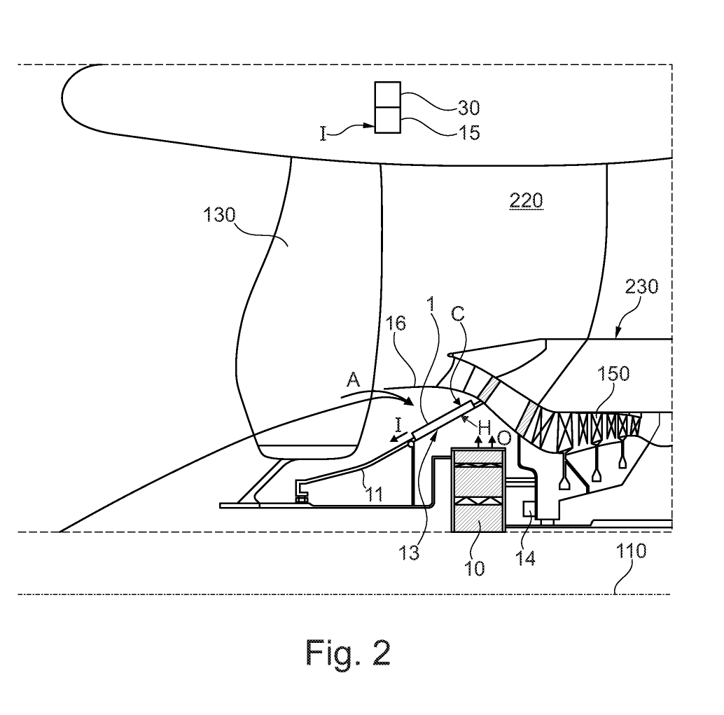

FIG. 2 shows a first embodiment of an energy conversion system in an aircraft engine;

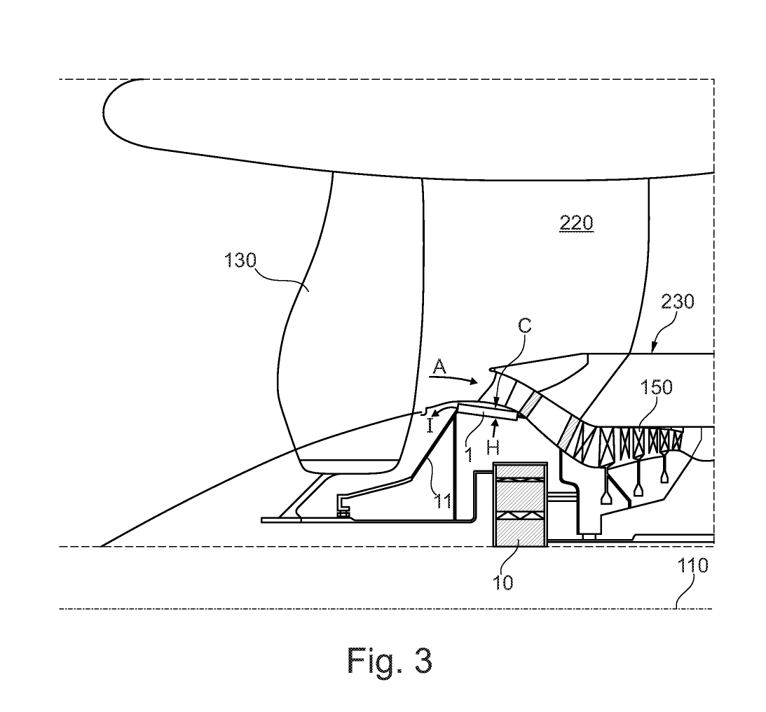

FIG. 3 shows a modification of the embodiment according to FIG. 2;

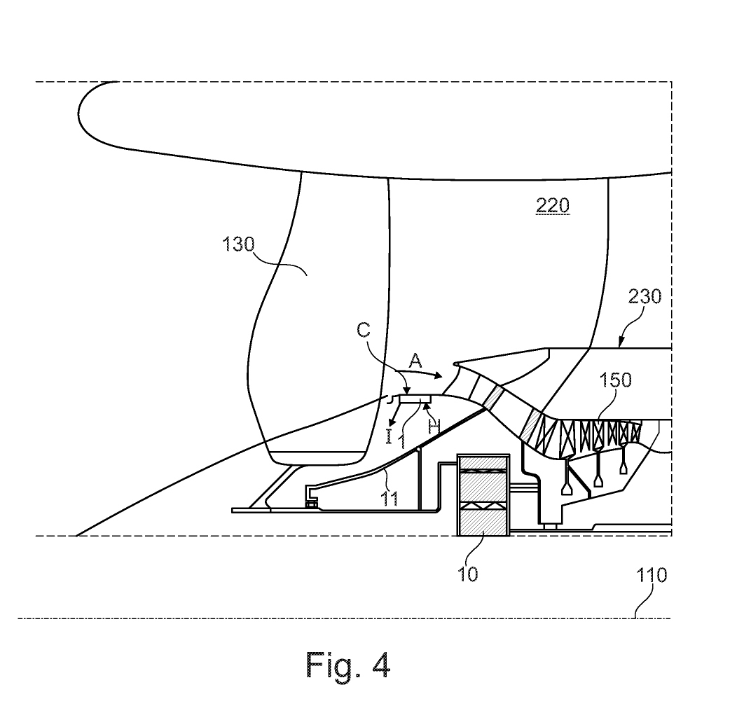

FIG. 4 shows a further embodiment of an energy conversion system in a modification of the embodiment according to FIG. 3;

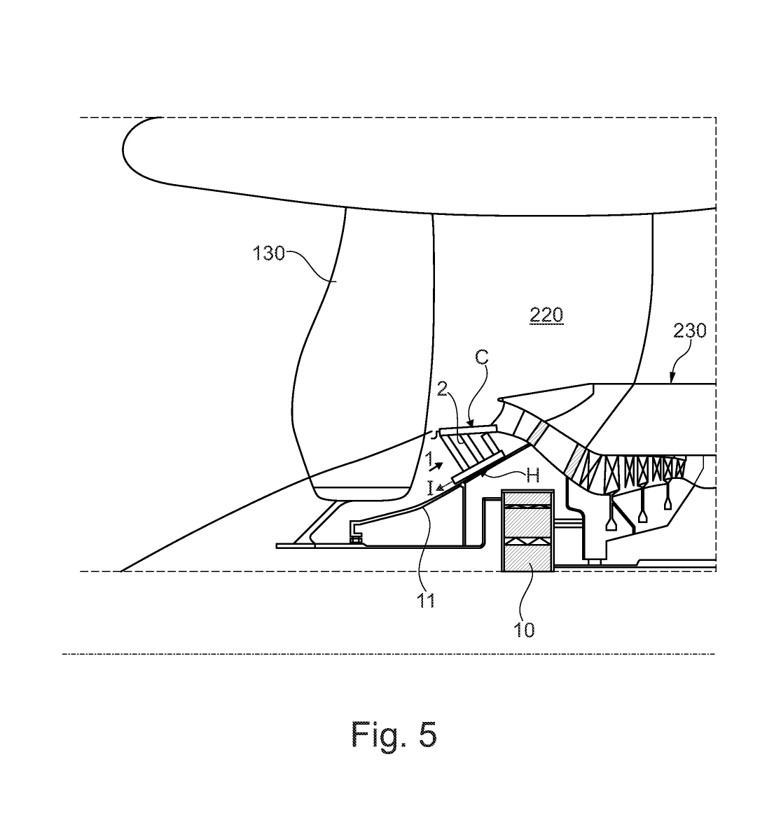

FIG. 5 shows a further embodiment of an energy conversion system in a modification of the embodiment according to FIG. 4;

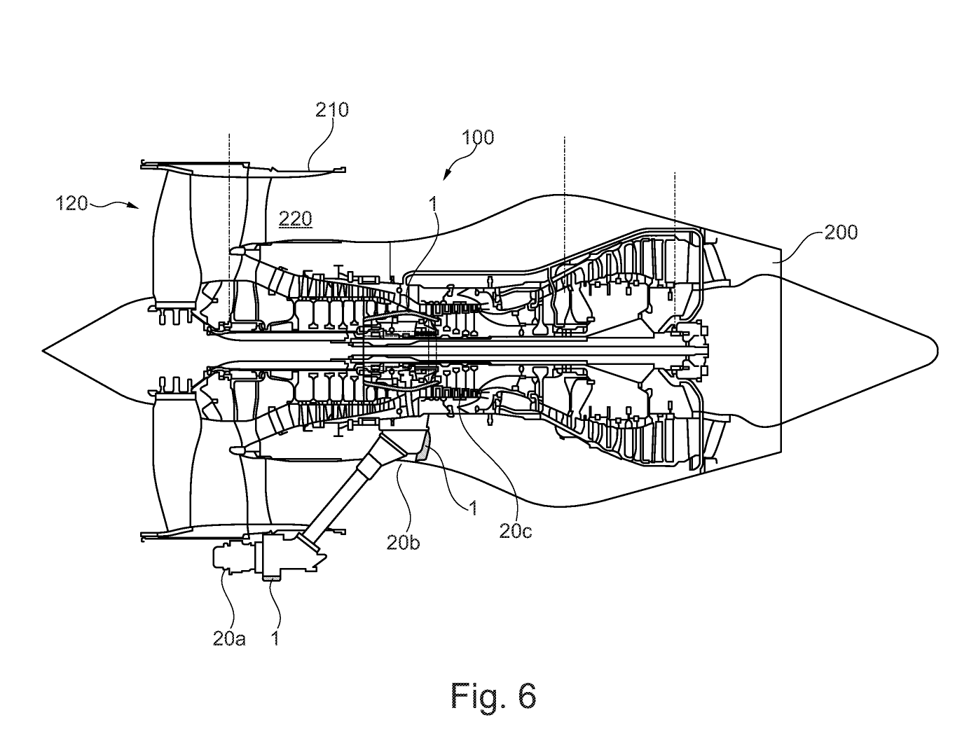

FIG. 6 shows a schematic view of an aircraft engine with further gear boxes and thermoelectric elements thermally coupled thereby;

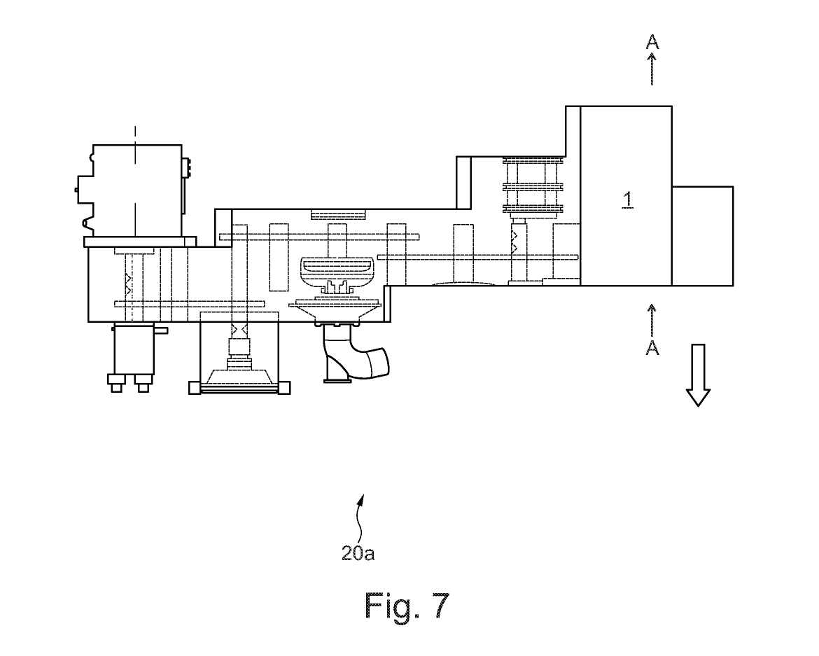

FIG. 7 shows a detailed view of a further gear box with a thermally coupled thermoelectric element;

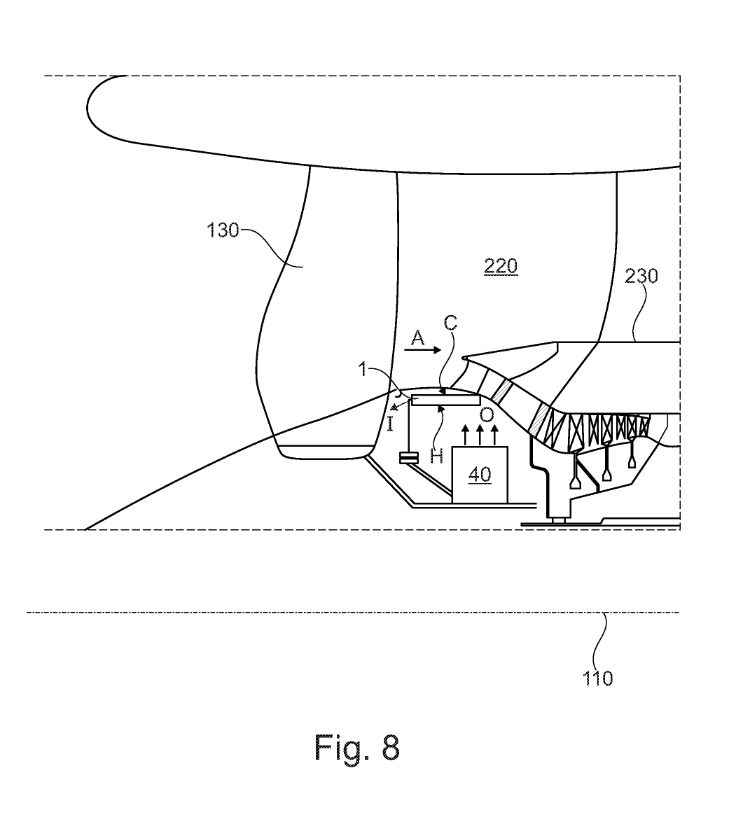

FIG. 8 shows a schematic view of an aircraft engine with a bearing housing and a thermoelectric element thermally coupled thereby as a further embodiment of an energy conversion system.

In FIG. 1, an aircraft engine 100 is schematically represented in the embodiment of a fan drive gear system with a power gear box 10. The aircraft engine 10 rotates about the axis of rotation 110.

The aircraft engine 100 comprises, in the essentially axial throughflow direction, an air inlet 120, a fan stage 130, which is assumed here to be part of a low-pressure compressor 150, a high-pressure compressor 160, a combustion chamber 170, a high-pressure turbine 180, a low-pressure turbine 190 and an outlet nozzle 200. A gondola 210 (also referred to as a nacelle) encloses the aircraft engine 100 and defines the air inlet 120.

The aircraft engine 100 operates in a known manner, so that the air entering the air inlet 120 is accelerated by the fan stage 130, wherein there are two air flows after the fan stage 130: a first air flow is guided into the low-pressure compressor 150 within the core engine 230, a second air flow is passed through a by-pass channel 220 to generate the main part of the thrust. The air not flowing through the by-pass channel 220 flows through a core engine 230.

The low-pressure and high-pressure compressors 150, 160 in the core engine 230 compress the air flow and pass the air for combustion into the combustion chamber 170. The hot combustion gases emanating from the combustion chamber 170 are expanded in the high-pressure and low-pressure turbines 180, 190 before exiting via the air outlet nozzle 200 to generate additional thrust.

The high-pressure turbine 180 and the low-pressure turbine 190 drive the high-pressure compressor 160 and the low-pressure compressor 150 respectively and the fan stage 130 via a suitable shaft arrangement. The high-pressure turbine 180, the low-pressure turbine 190, the high-pressure compressor 160 and/or the low-pressure compressor can each consist of a plurality of stages.

The power gear box 10 can comprise an epicyclical gear box with a planetary arrangement or a star arrangement. In other aircraft engines 100, alternative gear box configurations can be used, so that the embodiment in FIG. 1 only represents one possible embodiment. Also, the aircraft engine 100 can comprise a different number of shafts and/or a different number of compressors and/or turbines.

In FIG. 1, a housing 11 of the power gear box is only schematically represented. Sections of the housing 11 of different embodiments are represented in detail below.

In the embodiments according to FIGS. 2 through 7, two types of gear box 10, 20 are used in connection with an energy conversion system with thermoelectric elements 1, wherein first embodiments (FIGS. 1 through 5) are represented in connection with a power gear box 10.

As mentioned above, the power gear box 10 mechanically couples the low-pressure turbine stage 190, for example, to a compressor stage (for example, the fan stage 130) of the aircraft engine 100.

In a geared turbofan embodiment, an aircraft engine 100 comprises a reduction gear box (e.g. 3:1 through 4:1) as a power gear box 10 between the fan stage 130 and the low-pressure turbine 190. The revolution rate of the fan stage 130 can be reduced thereby and that of the low-pressure turbine 190 can be increased, so that both components of the aircraft engine 100 can operate in the respective optimal revolution rate ranges thereof. Consumption values and noise levels are significantly reduced as a result.

In the embodiments according to FIGS. 6 and 7, which can be combined with the other embodiments, a further gear box 20a, 20b, 20c is thermally coupled to a thermoelectric element 1.

Here a further gear box 20a, 20b, 20c means for example an external gear box 20a that is driven by the aircraft engine 100—for example by the outer compressor shaft (high-pressure compressor), and that may be disposed outside the core engine 230. The external gear box 20a is part of the so-called auxiliary section of the aircraft engine 100.

For example, fuel pumps (high-pressure and low-pressure), oil pumps, centrifugal oil separators, hydraulic pumps, generators for generating electricity of the aircraft and engine, a starter, a fuel control system and/or revolution rate sensors are disposed here and are driven by means of the main gear box 20.

In each case the gear boxes 10, 20 generate significant amounts of waste heat that must be dissipated. In the embodiments that are shown here, the thermal energy is used by thermoelectric elements 1. A thermoelectric element 1 produces a temperature difference (Peltier effect) when current is being passed or produces a current (Seebeck effect) when there is a temperature difference.

The present case concerns the generation of a current flow from a temperature difference at a gear box 10, 20, which is also referred to as energy harvesting.

The reason for the thermoelectric effect is as a rule the contact of two semiconductors in the thermoelectric element 1, which occupy a different energy level (either p-conducting or n-conducting) of the conduction bands. If current is passed through two successive contact points of said materials, then thermal energy must be absorbed at one contact point so that the electrons pass into the higher-energy conduction band of the adjacent semiconducting material, and consequently cooling takes place. At the other contact point, electrons fall from a higher energy level to a lower energy level, so that here energy is output in the form of heat.

Because n-doped semiconductors comprise a lower energy level of the conducting band, in this case the cooling takes place at the point at which the electrons transition from the n-doped semiconductor to the p-doped semiconductor (thus technically there is a current flow from the p-doped semiconductor to the n-doped semiconductor).

In FIG. 2, a first embodiment of an energy conversion system is represented, in which a thermoelectric element 1 is disposed on the outside of the housing 11 of the power gear box 10. The thermoelectric element 1 is embodied here in a known way as a flat component, in which the semiconducting elements are disposed. For the sake of simplicity, the thermoelectric element 1 is usually not shown in further detail as a result.

The power gear box 10 is disposed axially after the fan stage 130 (and also after the inlet cone 131) and before the low-pressure compressor 150.

In this case, a section of the aircraft engine 100 is represented, so that reference can be made to FIG. 1 and the description thereof.

The housing 11 envelops the power gear box 10 all-around and comprises a peripheral conical section. The thermoelectric element 1 is disposed in the form of a conically disposed strip also all-around the housing 11 here. In other embodiments, the thermoelectric element 1 only extends over part of the circumference of the housing 11.

In this case, the hot side H of the thermoelectric element 1 is facing the power gear box 10. In the interior of the housing 11, during operation oil O (symbolized in FIG. 2 by arrows) is strongly heated by the movement of the power gear box 10. The hot oil O transfers heat via a deflector 13 to the inner side of the housing 11, i.e. to the hot side H of the thermoelectric element 1.

The cold side C of the thermoelectric element 1 is oriented in the direction of a cooling air flow A that is passed through a means of guiding the cooling air 16, in this case a gap, specifically to the cold side C.

Thus, a temperature difference is produced by means of the thermoelectric element 1 that is converted into a current flow I, i.e. electrical energy. In the figures, the current flow I is represented here only symbolically for space reasons.

Thus, an energy conversion system is implemented, in which electrical energy is obtained from thermal energy if there is a temperature difference. The generated electrical energy can for example be used to operate a different unit of the aircraft engine 100, in particular an oil pump 14 of the power gear box 10 and/or a controller 15 (for example the EEC, FADEC) of the aircraft engine 100, or at least to provide auxiliary power for the same.

In FIG. 1, the controller 15 and an oil pump 14 are schematically represented. In the other figures, said units are not shown for reasons of clarity. The thermoelectric elements 1 are connected to the current controller 30 and/or the current consuming units, such as the controller 15 and/or the oil pump 14, via lines that are also not shown for reasons of clarity in the figures.

A current controller 30, which for reasons of clarity is also only represented in FIG. 2, is used to control the current arising, especially depending on the operating state of the aircraft engine 100. The operating state influences the temperature differences across the thermoelectric elements 1, so that for example in the full load region more current is available from the energy conversion systems than in the low load region. However, because the units can be partly or entirely supplied with current by means of the energy conversion systems, a more efficient power supply results in the aircraft engine.

An example of a calculation yields that electrical power of approx. 1 kW can be achieved if there is a temperature difference of 160° C. between the cold and hot sides C, H of the thermoelectric element 1. The area of the thermoelectric element 1 is approx. 0.2 m², the weight approx. 3.5 kg.

In FIG. 3, a further embodiment of the energy conversion system is represented, which differs from the embodiment according to FIG. 2 in that the flow of cooling air K is not passed through a gap in the core engine 230, but the air A flowing into the low-pressure compressor 150 is used for cooling. The cold side C of the thermoelectric element 1 is turned outwards in this case, the hot side H is disposed on the housing 11 of the power gear box 10. Otherwise, said embodiment corresponds to that shown in FIG. 2, so that the corresponding description can be referred to.

In FIG. 4, a further embodiment of the energy conversion system is represented, wherein here—as with the embodiment according to FIG. 3—the air flow A flowing past the core engine 230 is used to cool the cold side C of the thermoelectric element 1. The thermoelectric element 1 is however—in contrast to with the embodiment of FIG. 3—not disposed on the housing 11 but on the wall of the core engine 230. The heat transfer into the interior of the housing 11 also takes place in this case inter alia by bleed air escaping from the front bearing on the housing 11.

In FIG. 5, a further embodiment of the energy conversion system is represented, in which—as with the embodiment according to FIG. 4—the cold side C of the thermoelectric element 1 is disposed on the core engine 230. The hot side H of the thermoelectric element 1 is however—as with the embodiment of FIGS. 2 and 3—disposed on the housing 11 of the power gear box 10. Between the cold side C and the hot side H of the electrothermal element 1, semiconducting elements 2 are disposed that are necessary in any case for exploiting the Seebeck effect.

In FIGS. 2 through 8, embodiments using a power gear box as a fan drive gear system have been described.

In FIGS. 6 through 8, embodiments are described that can be operated alternatively or additionally to said fan drive gear system embodiments and with which at least one thermoelectric element 1 is thermally coupled to a further gear box 20a, 20b, 20c or a bearing housing 30 in order to convert thermal energy into electrical energy there.

In FIG. 6, a known aircraft engine 100 is represented with a series of further gear boxes 20a, 20b, 20c that heat up during operation, so the thermoelectric elements 1 can convert the respectively output thermal energy into electrical energy.

A first gear box is the external gear box 20a (also called the accessory gear box), which as a rule extends around the aircraft engine 100 to a certain angular extent (see also FIG. 7). A thermoelectric element 1 is disposed on the outside of the first gear box 20a that—as described in the other embodiments—produces electrical energy for full or assisted operation for example of controllers 15 or other units.

A second gear box 20b is a deflection gear box, which is additionally or alternatively provided with a thermoelectric element 1.

The third gear box 20c is an internal gear box that is also additionally or alternatively provided with a thermoelectric element 1.

A rough calculation shows that at a temperature difference of 80 to 110 60° C.—i.e. significantly lower than in the case of the power gear box 10—an electrical power of about 1 kW can be produced. In principle, it is possible to produce between 800 and 1600 W/m².

The temperature difference depends on the oil temperature in the gear box 20a, 20b, 20c. In this case, the temperature difference of 60° C. set here is set as the lower limit, which occurs during partial load operation, for example. At full load, a temperature difference of for example 160° C. can occur.

Because the generated electrical energy depends on the operating state of the aircraft engine 100, the current control arrangement 30 (see FIG. 2) can control which units 14, 15 in the aircraft engine 100 are supplied in which operating state. A unit with a relatively high current consumption, such as the oil pump 14, can for example be selectively supplied in full load operation by the thermoelectric element 1. On the other hand, a comparatively low consumer such as the controller 15 (EEC, FADEC) can be supplied continuously with electrical energy at full load, part load or low load from one of the energy conversion devices.

In FIG. 7, a top view of the first gear box, the external gear box 20a, is shown. The arrow on the right indicates the direction to the intake region of the aircraft engine 100 that is not shown here.

The thermoelectric element 1 is disposed here in the vicinity of an oil reservoir and cooling air A flows over it in the direction of the arrow.

Bearing housings 30, for example of a ball bearing, are thermally quite comparable to a gear box housing 11. Here too, significant thermal energy could occur, which can be converted into electrical energy by means of at least one thermoelectric element 1.

In FIG. 8, a bearing housing 40 of the front shaft bearing (front bearing) of the aircraft engine is schematically represented. Here too, the temperature difference across a thermoelectric element 1 can be used to produce electrical energy for the operation of other units. Similar to the power gear box, oil is heated in the front shaft bearing. The heat transfer is carried out by oil droplets in the interior of the housing 11.

### REFERENCE CHARACTER LIST

1 thermoelectric element
2 semiconducting element
10 power gear box
11 housing
13 deflector
14 oil pump
15 controller (EEC, FADEC)
16 means of guiding cooling air
20a external gear box (accessory gear box)
20b deflection gear box
20c internal gear box
30 current control arrangement
40 bearing housing
100 turbo engine, aircraft engine
110 axis of rotation
120 air inlet
130 fan stage
131 inlet cone
150 low-pressure compressor
160 high-pressure compressor
170 combustion chamber
180 high-pressure turbine
190 low-pressure turbine
200 outlet nozzle
210 gondola (nacelle)
220 by-pass channel
230 core engine
A air flow for cooling
C cold side of the thermoelectric element
H hot side of the thermoelectric element
I electrical energy, current flow
O oil in the housing of the power gear box

1. An energy conversion system for a turbo engine,
wherein
at least one gear box and/or at least one bearing housing for converting thermal energy into electrical energy is/are thermally coupled to at least one thermoelectric element.

2. The energy conversion system as claimed in claim 1, wherein the at least one thermoelectric element is thermally coupled via a housing of the at least one gear box.

3. The energy conversion system as claimed in claim 1, wherein the electrical energy generated by the at least one thermoelectric element can be used to operate at least one other unit of the turbo engine, in particular for an oil pump of the power gear box and/or a controller of the turbo engine.

4. The energy conversion system as claimed in claim 3, wherein a current control arrangement that controls the electrical energy generated by the at least one thermoelectric element as a function of the operating state of the turbo engine, in particular supplies the other units entirely or partly with current.

5. The energy conversion system as claimed in claim 1, wherein at least one deflector for oil droplets of the at least one gear box and/or a bearing, wherein the deflector is thermally coupled to the at least one thermoelectric element.

6. The energy conversion system as claimed in claim 1, wherein the at least one gear box is embodied as a power gear box for mechanically coupling at least one low-pressure compressor stage to at least one turbine stage or as a further gear box.

7. The energy conversion system as claimed in claim 1, wherein the at least one thermoelectric element is disposed in an aircraft engine, wherein the at least one thermoelectric element is disposed in the axial direction partly or entirely between the tip of the inlet cone and the power gear box.

8. The energy conversion system as claimed in claim 1, wherein the at least one thermoelectric element is disposed at least partly on the housing of the at least one gear box and/or the at least one bearing housing, in particular entirely around the circumference of the housing of the power gear box and/or on the core engine.

9. The energy conversion system as claimed in claim 1, wherein a means of guiding cooling air to the cold side of at least one thermoelectric element.

10. A gear box or bearing housing of a turbo engine with at least one energy conversion system as claimed in claim 1.

11. A turbo engine, in particular an aircraft engine or a geared turbofan aircraft engine, with at least one gear box and/or a bearing housing as claimed in claim 10.
